(19) United States
(12) Patent Application Publication
(10) Pub. No.: US 2023/0117806 A1
(43) Pub. Date: Apr. 20, 2023

(54) SEMICONDUCTOR PACKAGES AND METHODS FOR MANUFACTURING THEREOF

(71) Applicant: Infineon Technologies AG, Neubiberg (DE)

(72) Inventors: Thorsten MEYER, Regensburg (DE); Thomas BEHRENS, Wenzenbach (DE); Christian IRRGANG, Sinzing (DE); Frank ZUDOCK, Sinzing (DE)

(73) Assignee: Infineon Technologies AG, Neubiberg (DE)

(21) Appl. No.: 17/952,688

(22) Filed: Sep. 26, 2022

(30) Foreign Application Priority Data
Oct. 18, 2021 (DE) 10 2021 126 933.4

(51) Int. Cl. H01L 21/56; H01L 23/00; H01L 25/16; H01L 21/48; H01L 23/31; H01L 23/498; H01L 23/29

(52) U.S. Cl. CPC H01L 21/565; H01L 24/32; H01L 24/24; H01L 25/16; H01L 21/4828; H01L 21/4839; H01L 23/3185; H01L 24/19; H01L 23/49861; H01L 23/49844; H01L 23/295; H01L 24/73; H01L 2224/32245; H01L 2224/24175; H01L 2224/24137; H01L 2924/13091; H01L 2924/1431; H01L 2924/182; H01L 2224/73267

(57) ABSTRACT

Semiconductor packages and methods for manufacturing are disclosed. In one example, a method for manufacturing a semiconductor package includes providing an electrically conductive chip carrier including a mounting surface and a protrusion extending out of the mounting surface. At least one semiconductor chip is arranged on the mounting surface. The method further includes encapsulating the protrusion and the at least one semiconductor chip in an encapsulation material, wherein surfaces of the protrusion and the at least one semiconductor chip facing away from the mounting surface remain uncovered by the encapsulation material. An electrical redistribution layer is formed over the surfaces of the protrusion and the at least one semiconductor chip facing away from the mounting surface. The electrical redistribution layer provides an electrical connection between the protrusion and the at least one semiconductor chip.

### CROSS-REFERENCE TO RELATED APPLICATION

This Utility Patent application claims priority to German Patent Application No. 10 2021 126 933.4, filed Oct. 18, 2021, which is incorporated herein by reference.

### TECHNICAL FIELD

The present disclosure relates to semiconductor technology in general. More particular, the present disclosure relates to semiconductor packages and methods for manufacturing such semiconductor packages.

### BACKGROUND

In semiconductor packaging, one or multiple components of a semiconductor device may be encapsulated by an encapsulation material for securing the components against external influences, such as e.g. moisture or mechanical impact. Conventional packaging methods may suffer from various drawbacks. In one example, when using a laser and a plating process for manufacturing an electrical interconnection of a semiconductor chip, associated design rules may require undesired large pad dimensions and large pitches. In another example, a laminate for embedding a semiconductor chip may include ions and other contaminations which may represent a corrosion risk for electronic structures of the semiconductor chip. Manufacturers and developers of semiconductor packages are constantly striving to improve their products and methods for manufacturing thereof. It may thus be desirable to develop semiconductor packages and methods for manufacturing thereof avoiding as many of the existing drawbacks as possible.

### SUMMARY

An aspect of the present disclosure relates to a method for manufacturing a semiconductor package. The method comprises providing an electrically conductive chip carrier comprising a mounting surface and a protrusion extending out of the mounting surface. The method further comprises arranging at least one semiconductor chip on the mounting surface. The method further comprises encapsulating the protrusion and the at least one semiconductor chip in an encapsulation material, wherein surfaces of the protrusion and the at least one semiconductor chip facing away from the mounting surface remain uncovered by the encapsulation material. The method further comprises forming an electrical redistribution layer over the surfaces of the protrusion and the at least one semiconductor chip facing away from the mounting surface, wherein the electrical redistribution layer provides an electrical connection between the protrusion and the at least one semiconductor chip.

An aspect of the present disclosure relates to a semiconductor package. The semiconductor package comprises an electrically conductive chip carrier comprising a mounting surface and a carrier portion extending out of the mounting surface arranged laterally displaced to the mounting surface. The semiconductor package further comprises at least one semiconductor chip arranged on the mounting surface. The semiconductor package further comprises an encapsulation material encapsulating the carrier portion and the at least one semiconductor chip, wherein surfaces of the carrier portion and the at least one semiconductor chip facing away from the mounting surface are uncovered by the encapsulation material. The semiconductor package further comprises an electrical redistribution layer formed over the surfaces of the carrier portion and the at least one semiconductor chip facing away from the mounting surface, wherein the electrical redistribution layer provides an electrical connection between the carrier portion and the at least one semiconductor chip.

### BRIEF DESCRIPTION OF THE DRAWINGS

The accompanying drawings are included to provide a further understanding of aspects. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIG. 1 illustrates a flowchart of a method for manufacturing a semiconductor package in accordance with the disclosure.

FIG. 2 includes FIGS. 2A to 2G schematically illustrating a cross-sectional side view of a method for manufacturing a semiconductor package 200 in accordance with the disclosure.

FIG. 3 illustrates assembly and/or fabrication tolerances that may occur in a method in accordance with the disclosure.

FIG. 4 schematically illustrates a cross-sectional side view of a semiconductor package 400 in accordance with the disclosure.

FIG. 5 schematically illustrates a cross-sectional side view of a semiconductor package 500 in accordance with the disclosure.

FIG. 6 schematically illustrates a cross-sectional side view of a semiconductor package 600 in accordance with the disclosure.

FIG. 7 schematically illustrates a cross-sectional side view of a semiconductor package 700 in accordance with the disclosure.

FIG. 8 schematically illustrates a cross-sectional side view of a semiconductor package 800 in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense.

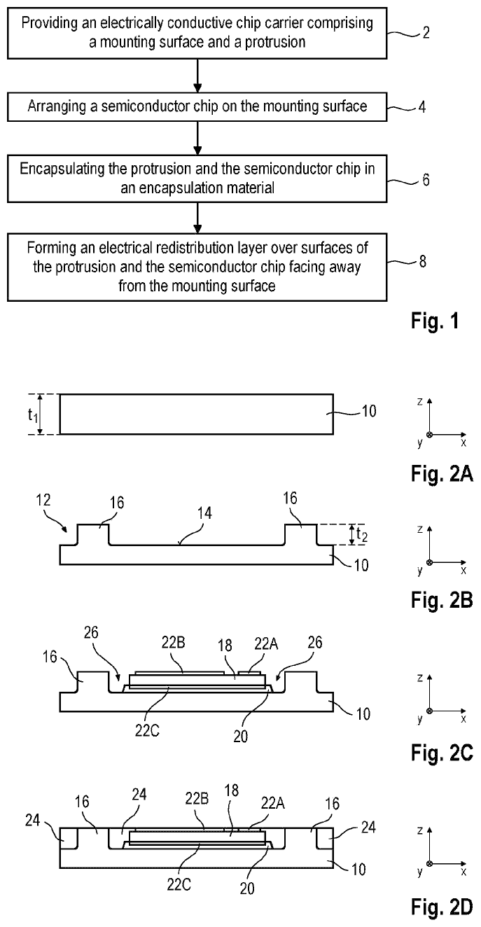

FIG. 1 illustrates a flowchart of a method for manufacturing a semiconductor package in accordance with the disclosure. The method is described in a general manner in order to qualitatively specify aspects of the disclosure and may include further aspects. For example, the method may be extended by any of the aspects described in connection with other examples in accordance with the disclosure.

At 2, an electrically conductive chip carrier including a mounting surface and a protrusion extending out of the mounting surface may be provided. At 4, at least one semiconductor chip may be arranged on the mounting surface. At 6, the protrusion and the at least one semiconductor chip may be encapsulated in an encapsulation material, wherein surfaces of the protrusion and the at least one semiconductor chip facing away from the mounting surface remain uncovered by the encapsulation material. At 8, an electrical redistribution layer may be formed over the surfaces of the protrusion and the at least one semiconductor chip facing away from the mounting surface, wherein the electrical redistribution layer provides an electrical connection between the protrusion and the at least one semiconductor chip.

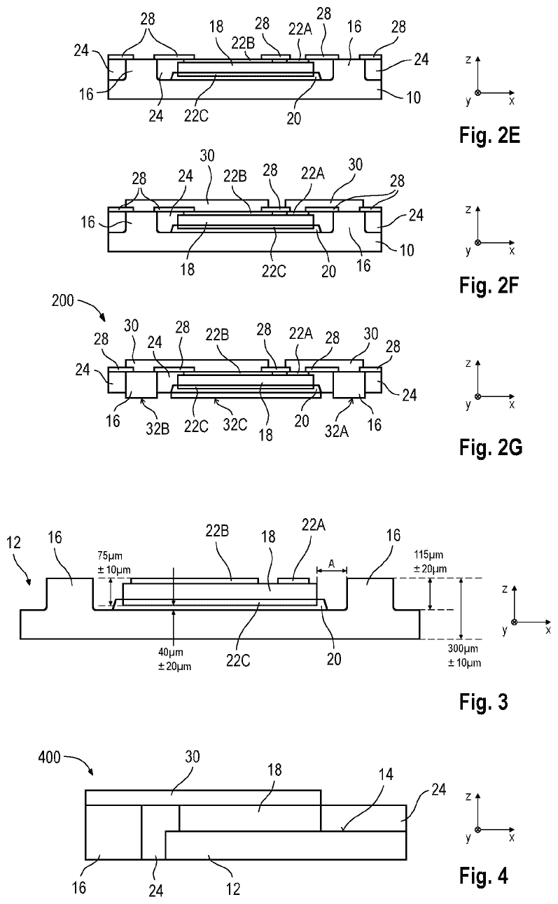

FIG. 2 includes FIGS. 2A to 2G and schematically illustrates a cross-sectional side view of a method for manufacturing a semiconductor package 200 in accordance with the disclosure. The method of FIG. 2 may be seen as a more detailed version of the method of FIG. 1. Comments made in connection with FIG. 2 may thus also apply to the previously described example of FIG. 1. The order of individual method acts discussed in connection with FIG. 2 is exemplary and non-limiting. At least some of the acts of the method may be exchanged, if reasonable and possible from a technical point of view. Furthermore, it is to be noted that each of the methods described herein may be performed as a batch process. That is, the individual method acts may be performed for an arbitrary number of similar arrangements.

In FIG. 2A, a layer made of an electrically conductive material may be provided. In the example of FIG. 2A, the electrically conductive layer may correspond to a metal sheet 10. The metal sheet 10 may be made of or may include any appropriate metal and/or metal alloy, in particular at least one of copper, copper alloys, nickel, iron nickel, etc. In the non-limiting example of FIG. 2A, the metal sheet 10 may be made of copper. When measured in the z-direction, a dimension t₁ of the metal sheet 10 may be smaller than about 500 μm, more particular smaller than about 450 μm, or even more particular smaller than about 400 μm. An exemplary non-limiting typical value of t₁ may be about 300 μm. Tolerances for t₁ may be about (±30 μm), more particular about (±20 μm), or even more particular about (±10 μm).

In FIG. 2B, the top surface of the metal sheet 10 may be structured, in particular by removing material from the top surface of the metal sheet 10. In one example, material may be removed by etching the top surface of the metal sheet 10. Alternatively or additionally, the metal sheet 10 may be structured based on a different technique, such as e.g. cutting, stamping, milling, etc.

When structuring the top surface of the metal sheet 10, an electrically conductive chip carrier 12 including one or multiple mounting surfaces 14 and one or more protrusions (or elevations) 16 extending out of the mounting surface 14 may be formed. In the non-limiting example of FIG. 2B, exemplary numbers of one mounting surface 14 and two protrusions 16 are shown. In further examples, the number of mounting surfaces 14 and protrusions 16 may differ, depending on the type of semiconductor package that is to be fabricated.

When measured in the z-direction, the protrusions 16 may have a dimension of t₂. For example, a ratio t₂/t₁ may have a value in a range from about ¼ to about ¾. In one specific example the ratio t₂/t₁ may have a value of about ½. The structured electrically conductive chip carrier 12 may include or may correspond to a leadframe, in particular a half etched leadframe. The semiconductor package that is to be manufactured may thus correspond to a leadframe based package.

As will become apparent later on, the protrusions 16 may become electrical connections in the semiconductor package that is to be fabricated. A size and a shape of the protrusions 16, in particular when viewed in the z-direction, may thus depend on a desired electrical connection type and associated electrical current densities. In one example, the protrusions 16 may be associated with logical signals based on low voltages and small current densities. Here, the protrusions 16 may be formed as columns or pedestals with a circular or rectangular cross section similar to via through connections. In a further example, the protrusions 16 may be associated with electrical power currents and high voltages. In such case, the protrusions 16 may have elongated shapes when viewed in the z-direction, for example bar-shaped, L-shaped, ring-shaped, etc.

In FIG. 2C, a semiconductor chip 18 may be arranged on the mounting surface 14 of the chip carrier 12. It is noted that throughout this description, the terms “chip”, “semiconductor chip”, “die”, “semiconductor die” may be interchangeably used. In general, semiconductor chips described herein may be manufactured from an elemental semiconductor material (e.g. Si) or from a wide band gap semiconductor material or a compound semiconductor material (e.g. SiC, GaN, SiGe, GaAs). The semiconductor chip 18 may include a power semiconductor component and may thus be referred to as power semiconductor chip. Power semiconductor chips may be used in any kind of power application like e.g. MOSFETs (Metal Oxide Semiconductor Field Effect Transistors), half bridge circuits, power modules including a gate driver, etc. For example, power chips may include or may be part of a power device like e.g. a power MOSFET, an LV (low voltage) power MOSFET, a power IGBT (Insulated Gate Bipolar Transistor), a power diode, a superjunction power MOSFET, etc.

In the specific example of FIG. 2C, the semiconductor chip 18 may correspond to a vertical power transistor including a gate electrode 22A and a source electrode 22B arranged on the top surface of the semiconductor chip 18 as well as a drain electrode 22C arranged on the bottom surface of the semiconductor chip 18. In further examples, the semiconductor chip 18 may correspond to a lateral power transistor having a lateral current flow, wherein all of the mentioned chip electrodes may be arranged on a same surface of the chip.

Any appropriate method may be used for attaching the semiconductor chip 18 to the mounting surface 14, for example at least one of gluing, soldering, sintering, etc. In the example of FIG. 2C, a mechanical connection between the chip carrier 12 and the semiconductor chip 18 may be provided by a die attach material (or adhesive material) 20. The die attach material 20 may be electrically conductive in order to provide an electrical connection between the drain electrode 22C and the electrically conductive chip carrier 12. After arranging the semiconductor chip 18 on the mounting surface 14, the top surfaces of the protrusions 16 and the semiconductor chip 18 facing away from the mounting surface 14 may be arranged substantially on a same level. In this regard, assembly and/or fabrications tolerances may occur which are shown and discussed in connection with FIG. 3. One or more gaps 26 may be formed between the semiconductor chip 18 and the protrusions 16.

In FIG. 2D, the semiconductor chip 18 and the protrusions 16 may be encapsulated in an encapsulation material 24. During and after the encapsulation act, the top surfaces of the protrusions 16 and the semiconductor chip 18 facing away from the mounting surface 14 may at least partly remain uncovered by the encapsulation material 24. In this regard, it is to be noted that not necessarily the entire top surfaces of the protrusions 16 and the semiconductor chip 18 may remain uncovered by the encapsulation material 24. In one example, at least the electrical contacts 22A and 22B arranged at the top surface of the semiconductor chip 18 may be uncovered by the encapsulation material 24 after the encapsulation act. The top surfaces of the protrusions 16 and the semiconductor chip 18 facing away from the mounting surface 14 may be flush with the top surface of the encapsulation material 24. That is, these top surfaces may be arranged in a common plane.

In one example, encapsulating the protrusions 16 and the semiconductor chip 18 may include a molding act. The encapsulation material 24 may include at least one of a molding compound, an epoxy, a filled epoxy, a glass fiber filled epoxy, an imide, a thermoplast, a thermoset polymer, a polymer blend, etc. Various techniques may be used for applying the encapsulation material 24, for example at least one of compression molding, injection molding, powder molding, liquid molding, map molding, etc.

In a more specific example, the protrusions 16 and the semiconductor chip 18 may be encapsulated based on a film-assisted molding (FAM) technique. Here, a mold tool (not illustrated) may be provided, wherein inner surfaces of the mold tool may be covered by a film (or foil). The arrangement of FIG. 2C may be placed in the mold tool. The mold tool may be closed, wherein the top surfaces of the protrusions 16 and the semiconductor chip 18 may be covered by a portion of the film arranged on the inner surfaces of the mold tool. After closing the mold tool the encapsulation material 24 may be applied or injected into interior of the mold tool. During the molding act, the surfaces of the protrusions 16 and the semiconductor chip 18 facing away from the mounting surface 14 may be covered by the film. After finishing the molding act, the mold tool may be opened and the molded arrangement may be removed from the mold tool.

It is understood that due to assembly and/or fabrication tolerances the top surfaces of the protrusions 16 and the semiconductor chip 18 may not necessarily be arranged at exact the same level. Note that possible height tolerances of at least one of the protrusions 16, the semiconductor chip 18 and the die attach material 20 are shown and discussed in connection with FIG. 3. In order to guarantee uncovered top surfaces after the molding process, the film used in the film assisted molding process may need to securely cover the top surfaces during the molding act. Accordingly, the film may be configured to compensate for present height tolerances. In particular, the film may be elastic to a certain extent for appropriately compensating the occurring height tolerances.

The following table provides information on how a film used in a film assisted molding act may compensate the mentioned height tolerances. The given values are exemplary and non-limiting and may be different for other film materials.

| | Chip Height | Chip |
|---|---|---|
| Film Thickness | Tolerance | Protrusion/Intrusion |
| (in μm) | (in mm) | (in mm) |
| 50 | 0.02 | 0.005 |
| 70 | 0.028 | 0.005 |
| 100 | 0.04 | 0.01 |
| 200 | 0.08 | 0.02 |

The first column of the table includes possible values for a thickness of the film, the second column includes associated values for a height tolerance of the semiconductor chip 18, and the third column includes associated values for a protrusion/intrusion of the semiconductor chip 18 with respect to the encapsulation material 24 after the molding process. For example, the first line of the table relates to using a film having a thickness of about 50 μm. A film of such thickness may be configured to compensate for a height difference of up to 20 μm, for example a height difference between a protrusion 16 and the semiconductor chip 18. After the molding act, the top surface of the semiconductor chip 18 may be uncovered by the molding compound. Here, the top surface of the semiconductor chip 18 may slightly protrude out of the top surface of the molding compound 24 by a value of about 5 μm or may slightly intrude into the top surface of the molding compound 24 by a value of about 5 μm.

During a molding act performed in connection with FIG. 2D, the molding compound 24 may at least partly fill one or multiple of the gaps 26. The molding compound 24 may include fillers (or filler particles) having a maximum filler size or diameter which may be referred to as filler cut. A filler cut of the fillers may be in a range from about 15 μm to about 100 μm, more particular from about 20 μm to about 80 μm. In a more specific example, fillers of a fine molding compound may have a filler cut of about 20 μm (as e.g. used for a molded underfill). In a further more specific example, fillers of a conventionally used molding compound may have a filler cut of about 45 μm or of about 75 μm. When mounting the semiconductor chip 18 on the mounting surface 14, a distance between the semiconductor chip 18 and the respective protrusion 16 may be greater than a minimum value. In particular, the distance between the semiconductor chip 18 and the respective protrusion 16 may be at least about two times the filler cut, more particular at least about two and a half times the filler cut, and even more particular at least three times the filler cut.

In a further method act (not illustrated) performed after the encapsulation of the protrusions 16 and the semiconductor chip 18, the top surfaces of the arrangement of FIG. 2D may be cleaned. For example, an associated cleaning act may include at least one of plasma cleaning, wet chemistry cleaning, laser cleaning, etc.

In FIG. 2E, a dielectric layer 28 may be applied to the top surface of the arrangement. Applying the dielectric layer 28 may be based on or may include at least one of printing, laminating, etc. The dielectric layer 28 may be applied for electric isolation purposes. For example, the applied dielectric layer 28 may cover and may thus electrically isolate chip edges at the top surface of the semiconductor chip 18 protruding out of the encapsulation material 24. The dielectric layer 28 may be structured and may include openings at the positions of the protrusions 16 and the chip electrodes 22A, 22B for a later electrical connection. Structuring the dielectric layer 28 may be based on or may include at least one of lithography, LDI (Laser Direct Imaging), using a mask aligner, using a stepper, etc. In a further example, the dielectric layer 28 may be applied in a structured manner, e.g. based on a printing technique, such as screen printing. The dielectric layer 28 may also be configured to provide a stress relief in order to avoid warpage of the arrangement which e.g. may be caused by different coefficients of thermal expansion of at least one of the chip carrier 12, the semiconductor chip 18 and the encapsulation material 24.

In FIG. 2F, an electrical redistribution layer 30 may be formed over the dielectric layer 28, thereby providing an electrical connection between the protrusions 16 and the semiconductor chip 18. In the example of FIG. 2F, the electrical redistribution layer 30 may provide an electrical connection between the gate electrode 22A and the protrusion 16 on the right, as well as an electrical connection between the source electrode 22B and the protrusion 16 on the left. The electrical redistribution layer 30 may be fabricated from any appropriate electrically conductive material such as e.g. metals and/or metal alloys. In this regard, the electrical redistribution layer 30 may include one or multiple metal layers or metal lines. In one example, the electrical redistribution layer 30 may include or may be made of copper and/or a copper alloy.

The fabrication of the electrical redistribution layer 30 is not restricted to a specific technique. In one example, forming the electrical redistribution layer 30 may be based on thin film technology. Thin film deposition is a technology of applying a very thin film of material onto a surface that is to be coated. In general, a thin film may have a thickness between about a few nanometers to about 100 micrometers. Thin film technology may be based on chemical deposition and/or physical deposition.

In one example, the electrical redistribution layer 30 may be manufactured based on an additive method which may e.g. include at least one of printing, jetting, sintering, etc. In a further example, the electrical redistribution layer 30 may be manufactured based on a semi-additive method which may e.g. include the acts of sputtering and electroplating. For example, a seed layer may be sputtered on the top surface of the arrangement and a plating resist may be applied onto the sputtered seed layer. In one example, the seed layer may include multiple layers. Here, the seed layer may e.g. include a barrier layer (made of e.g. at least one of Ti, TiW, Cr) and the actual seed layer (made of e.g. Cu). The plating resist may be removed at positions of the protrusions 16 and the electrodes 22A, 22B, and a metal (e.g. copper) may be electroplated into the openings. Remaining portions of the seed layer and the plating resist may be removed by an etching act afterwards. In yet a further example, a subtractive method may be used for manufacturing the electrical redistribution layer 30. Here, a full area plating act may be followed by a structured etching process. Besides the already mentioned techniques, any further suitable methods may be used for fabricating the electrical redistribution layer 30, such as e.g. electro-less plating.

In one or multiple further acts, a second dielectric layer (not illustrated) may be formed over the electrical redistribution layer 30. In addition, a second electrical redistribution layer (not illustrated) may be formed over the second dielectric layer. The second electrical redistribution layer may be electrically connected to the electrical redistribution layer 30 at one or multiple specific positions. In addition, the second dielectric layer may be arranged between the two electrical redistribution layers at positions where an electrical isolation between the redistribution layers may be desired. An arbitrary number of further dielectric layers and electrical redistribution layers may be manufactured such that a multilayer electrical redistribution stack may be obtained.

The semiconductor package that is to be manufactured may include further electronic components which are not shown for the sake of simplicity, such as e.g. further semiconductor chips or passives. At least some of these further electronic components may be arranged on the mounting surface 14 and may be electrically interconnected by at least one of the protrusions 16 and the electrical redistribution layers. Note that passives may also be formed by structuring one or multiple of the electrical redistribution layers. A multilayer redistribution stack may be configured to provide a high number of electrical connections between the semiconductor chip 18 and further electronic components of the semiconductor package.

In FIG. 2G, the bottom surface of the metal sheet 10 may be structured, wherein electric contacts elements 32A, 32B and 32C may be formed from the material of the metal sheet 10. In one example, structuring the bottom surface of the metal sheet 10 may include an etching act. Due to the structuring of the bottom surface, the protrusions 16 may be separated from other parts of the metal sheet 10. The separated protrusions 16 may herein also be referred to as carrier portions. The carrier portions (or former protrusions) 16 may form an electrical through connection extending from the bottom surface of the encapsulation material 24 to the top surface of the encapsulation material 24.

A first electrical contact element 32A may be electrically connected to the gate electrode 22A of the semiconductor chip 18 via the carrier portion 16 on the right and the electrical redistribution layer 30. In a similar fashion, a second electrical contact element 32B may be electrically connected to the source electrode 22B of the semiconductor chip 18 via the carrier portion 16 on the left and the electrical redistribution layer 30. In addition, a third electrical contact element 32C may be electrically connected to the drain electrode 22C of the semiconductor chip 18 via the die attach material 20. Accordingly, the electrodes 22A to 22C of the semiconductor chip 18 may be electrically accessible via the electrical contacts 32A to 32C. The obtained semiconductor package 200 may be electrically and mechanically connected to a further component (not illustrated), such as e.g. a printed circuit board, via the electrical contact elements 32A to 32C.

The method of FIG. 2 may include further acts which are not illustrated for the sake of simplicity. In a further possible act, an electrically insulating material may be arranged on the bottom surface of the arrangement between the electrical contact elements 32A to 32C. For example, the electrically insulating material may include a molding compound applied based on a molding act. Alternatively, the electrically insulating material may be a material applied based on a printing process. In another further possible act, the top surface of the semiconductor package 200 may be covered by a material layer, such as e.g. a molding compound, a solder stop material, or any other suitable passivation layer. A molding compound arranged over the top surface of the semiconductor package 200 may be manufactured in a single molding act together with the molding compound 24 encapsulating the semiconductor chip 18 and the carrier portions 16.

The method of FIG. 2 and other methods in accordance with the disclosure may avoid drawbacks that may occur in conventional methods for manufacturing semiconductor packages. For example, conventional methods may include a laser drilling act for accessing contact pads on the top surface of the semiconductor chip. Such conventional approach may have the following drawbacks. The laser drilling may need to be performed without direct alignment to the semiconductor chip which may require large pads (e.g. having a pad size of larger than about 250 μm, typically about 260 μm) in order to be able to hit the pads. In addition, pad pitches may have to be large enough to avoid electrical shorting. The pads may have to consist of thick copper layers (e.g. having a thickness above about 5 μm and/or smaller than about 20 μm) in order to allow the laser to remove the material above the pad without destroying the sensitive semiconductor chip. Such thick copper layers may be costly and may cause warpage to the semiconductor wafer. In addition, laser drilling may be a costly process. Finally, the pads may need to be cleaned after the laser drilling in order to allow for a proper electrical interconnection.

The described drawbacks of laser drilling may be avoided when using the method of FIG. 2. After the encapsulation act of FIG. 2D, the top surface of the arrangement may be directly accessible for performing one or multiple method acts as previously described. No laser drilling for accessing the chip pads may be required. The contact pads of the semiconductor chip 18 may therefore not require a special pad metallization. This way, also small semiconductor chips, such as e.g. SiC chips, having small source pads and gate pads may easily be contacted with the full coverage of the source pad by the electrical redistribution layer 30. In addition, small pad distances between the source electrode and the gate electrode may represent no issue and may be reliably connected without the risk of electrical shorting. In general, methods in accordance with the disclosure may offer a routing capability with very tight design rules, because a placement tolerance of the electrical redistribution layer 30 may e.g. be about ±2 μm. Such design rules may allow for a full metal areal contact of the source pad and small pitches to a small gate pad.

In another example, conventional methods may use laminate materials for embedding semiconductor chips of a semiconductor package. Compared to molding compounds, such laminate materials may be less well known and may potentially contain impurities, such as e.g. ions or other contaminations, which may cause a higher reliability risk compared to a molding compound. The method of FIG. 2 and other methods in accordance with the disclosure may avoid usage of laminate materials and may thus reduce potential damage to the semiconductor chip 18.

Besides the described avoidance of drawbacks, methods in accordance with the disclosure may provide a high electrical performance due to the electrical redistribution layer 30 and an areal interconnect at the source electrode 22B and the drain electrode 22C. In addition, a good thermal performance may be provided due to a thick metal capability under the semiconductor chip 18.

FIG. 3 illustrates assembly and/or fabrication tolerances that may occur in a method in accordance with the disclosure. The arrangement of FIG. 3 may be similar to the arrangement shown and described in connection with FIG. 2C. Note that the following values are exemplary and non-limiting. A dimension of the die attach material 20 in the z-direction may be about 40 μm with a tolerance of about ±20 μm. A dimension of the protrusions 16 in the z-direction may be about 115 μm with a tolerance of about ±20 μm. Measured in the z-direction, a distance from the bottom surface of the chip carrier 12 to the top surface of a protrusion 16 may be about 300 μm with a tolerance of about ±10 μm. Measured in the z-direction, a distance from the bottom surface of the drain electrode 22C of the semiconductor chip 18 to the top surface of the source electrode 22B of the semiconductor chip 18 may be about 75 μm with a tolerance of about ±10 μm. As already discussed in connection with FIG. 2D, a film (or foil) used in a film assisted molding act may be configured to compensate for the tolerances shown in FIG. 3.

In FIG. 3, “A” denotes a distance between the semiconductor chip 18 and a protrusion 16 when measured in the x-direction. The distance “A” may be at least about two times the filler cut of a molding compound encapsulating the semiconductor chip 18, more particular at least about two and a half times the filler cut, and even more particular at least three times the filler cut. Other than that, the distance “A” may be arbitrarily chosen. In some examples, the distance “A” may be in a range from about 200 μm to about 500 μm.

The semiconductor package 400 of FIG. 4 is illustrated in a general manner in order to qualitatively specify aspects of the disclosure. The semiconductor package 400 may include further aspects which are not illustrated for the sake of simplicity. For example, the semiconductor package 400 may be extended by any of the aspects described in connection with other semiconductor packages and methods in accordance with the disclosure. For example, the semiconductor package 400 may be manufactured based on the method of FIG. 1.

The semiconductor package 400 may include an electrically conductive chip carrier 12 comprising a mounting surface 14 and a carrier portion 16 extending out of the mounting surface 14 arranged laterally displaced to the mounting surface 14. Note that the carrier portion 16 may correspond to a former protrusion of the chip carrier 12 as described in connection with foregoing figures. At least one semiconductor chip 18 may be arranged on the mounting surface 14. An encapsulation material 24 may encapsulate the carrier portion 16 and the at least one semiconductor chip 18, wherein surfaces of the carrier portion 16 and the at least one semiconductor chip 18 facing away from the mounting surface 14 may be uncovered by the encapsulation material 24. An electrical redistribution layer 30 may be formed over the surfaces of the carrier portion 16 and the at least one semiconductor chip 18 facing away from the mounting surface 14, wherein the electrical redistribution layer 30 may provide an electrical connection between the carrier portion 16 and the at least one semiconductor chip 18.

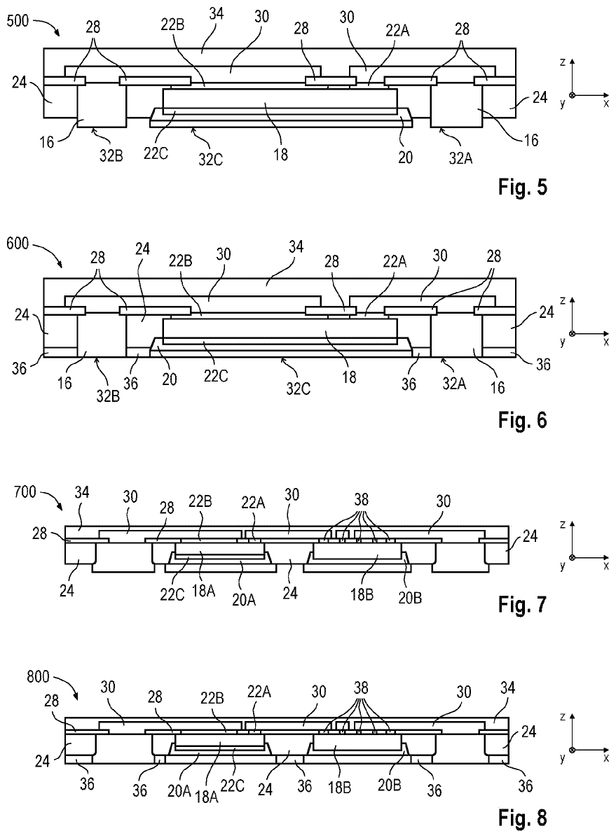

The semiconductor package 500 of FIG. 5 may be seen as a more detailed version of the semiconductor package 400 of FIG. 4. The semiconductor package 500 may include some or all of the features of the semiconductor package 200 of FIG. 2G. Compared to FIG. 2G, the semiconductor package 500 may include a material layer 34 covering the top surface of the arrangement. In particular, the material layer 34 may be electrically insulating. For example, the material layer 34 may include or may be made of a molding compound, a solder stop material, or any other suitable passivation layer. For the case of a molding compound, the material layer 34 may have been manufactured in a single molding act together with a molding compound 24 encapsulating the semiconductor chip 18.

The semiconductor package 600 of FIG. 6 may include some or all of the features of the semiconductor package 500 of FIG. 5. Compared to FIG. 5, the semiconductor package 600 may include an electrically insulating material 36 arranged at the bottom surface of the arrangement between the electrical contact elements 32A to 32C. The electrically insulating material 36 may e.g. include a molding compound applied based on a molding act. Alternatively, the electrically insulating material 36 may be a material applied based on a printing process.

The semiconductor package 700 of FIG. 7 may include some or all of the features of the semiconductor package 500 of FIG. 5. Compared to FIG. 5, the semiconductor package 700 may include two semiconductor chips 18A and 18B. In the example of FIG. 7, a first semiconductor chip 18A may be similar to the semiconductor chip 18 of FIG. 2 and may e.g. correspond to a power semiconductor chip, such as e.g. a power MOSFET. A second semiconductor chip 18B may include one or multiple contact pads 38 arranged at the top surface of the second semiconductor chip 18B. The semiconductor chips 18A and 18B may be electrically interconnected via the electrical redistribution layer 30.

The second semiconductor chip 18B may be a non-power chip, i.e. any kind of semiconductor chip which may not be considered a power semiconductor chip. For example, a non-power chip may include at least one of a sensor chip, a logic chip, a memory chip, etc. A sensor chip may be configured to sense a physical variable, for example pressure, temperature, humidity, accelerations, etc. In one example, a sensor chip may be a MEMS (Micro-Electro-Mechanical System) chip including a MEMS structure which may be integrated in the chip. A logic chip may be configured to process electrical signals provided by other electronic components of the semiconductor package 700. For example, the logic chip may include an application specific integrated circuit (ASIC). Additionally or alternatively, a logic chip may be configured to control and/or drive other electronic components of the semiconductor package 700. In one example, a logic chip may be configured to control and/or drive integrated circuits of the power semiconductor chip 18A. Here, one or more of the contact pads 38 of the second semiconductor chip 18B may be electrically connected to the gate electrode 22A of the first semiconductor chip 18A.

It is to be noted that a number of semiconductor chips and/or electronic components included in a semiconductor package in accordance with the disclosure is not restricted to a specific value. In further examples, the semiconductor package 700 may also include three or more semiconductor chips as well as one or multiple passive components. In a more specific example, the semiconductor package 700 may include three semiconductor chips which may be electrically interconnected to form a half bridge circuit. Here, a first power semiconductor chip and a second power semiconductor may correspond to a low side switch and a high side switch of the half bridge circuit, respectively. A logic semiconductor chip may be configured to control and/or drive at least one of the first power semiconductor chip and the second power semiconductor chip. In particular, the logic semiconductor chip may include a driver circuit configured to drive the high side switch and the low side switch of the half bridge circuit.

The semiconductor package 800 of FIG. 8 may include some or all of the features of the semiconductor package 700 of FIG. 7. Compared to FIG. 7, the semiconductor package 800 may include an electrically insulating material 36 arranged at the bottom surface of the arrangement as already discussed in connection with FIG. 6.

### Examples

In the following, semiconductor packages and methods for manufacturing such semiconductor packages in accordance with the disclosure will be explained by means of examples.

Example 1 is a method for manufacturing a semiconductor package, the method comprising: providing an electrically conductive chip carrier comprising a mounting surface and a protrusion extending out of the mounting surface; arranging at least one semiconductor chip on the mounting surface; encapsulating the protrusion and the at least one semiconductor chip in an encapsulation material, wherein surfaces of the protrusion and the at least one semiconductor chip facing away from the mounting surface remain uncovered by the encapsulation material; and forming an electrical redistribution layer over the surfaces of the protrusion and the at least one semiconductor chip facing away from the mounting surface, wherein the electrical redistribution layer provides an electrical connection between the protrusion and the at least one semiconductor chip.

Example 2 is a method according to Example 1, wherein forming the electrical redistribution layer is based on a thin film technology.

Example 3 is a method according to Example 1 or 2, wherein encapsulating the protrusion and the at least one semiconductor chip comprises a molding act.

Example 4 is a method according to Example 3, wherein during the molding act the surfaces of the protrusion and the at least one semiconductor chip facing away from the mounting surface are covered by a film.

Example 5 is a method according to Example 4, wherein during the molding act the film is configured to compensate for height tolerances of at least one of the protrusion, the at least one semiconductor chip and a die attach material arranged between the at least one semiconductor chip and the mounting surface.

Example 6 is a method according to one of the preceding Examples, wherein providing the chip carrier comprises: providing a metal sheet; and removing material from a first surface of the metal sheet, thereby forming the protrusion.

Example 7 is a method according to Example 6, wherein removing the material from the first surface comprises etching the first surface.

Example 8 is a method according to Example 6 or 7, further comprising: structuring a second surface of the metal sheet opposite to the first surface, thereby forming electric contact elements configured for a connection to a printed circuit board.

Example 9 is a method according to Example 8, wherein at least one of the electric contact elements is electrically connected to the at least one semiconductor chip via the protrusion and the electrical redistribution layer.

Example 10 is a method according to Example 8 or 9, further comprising: arranging an electrically insulating material between the electrical contact elements.

Example 11 is a method according to one of the preceding Examples, further comprising: forming a dielectric layer over the electrical redistribution layer; and forming a further electrical redistribution layer over the dielectric layer, wherein the further electrical redistribution layer is electrically connected to the electrical redistribution layer.

Example 12 is a semiconductor package, comprising: an electrically conductive chip carrier comprising a mounting surface and a carrier portion extending out of the mounting surface arranged laterally displaced to the mounting surface; at least one semiconductor chip arranged on the mounting surface; an encapsulation material encapsulating the carrier portion and the at least one semiconductor chip, wherein surfaces of the carrier portion and the at least one semiconductor chip facing away from the mounting surface are uncovered by the encapsulation material; and an electrical redistribution layer formed over the surfaces of the carrier portion and the at least one semiconductor chip facing away from the mounting surface, wherein the electrical redistribution layer provides an electrical connection between the carrier portion and the at least one semiconductor chip.

Example 13 is a semiconductor package according to Example 12, wherein the electrical redistribution layer comprises a thin film electrical redistribution layer.

Example 14 is a semiconductor package according to Example 12 or 13, wherein the chip carrier comprises a leadframe.

Example 15 is a semiconductor package according to one of Examples 12 to 14, wherein the carrier portion forms an electrical through connection extending from a first surface of the encapsulation material to a second surface of the encapsulation material opposite to the first surface.

Example 16 is a semiconductor package according to one of Examples 12 to 15, wherein the surfaces of the carrier portion and the at least one semiconductor chip facing away from the mounting surface are arranged substantially on a same level.

Example 17 is a semiconductor package according to one of Examples 12 to 16, wherein the surfaces of the carrier portion and the at least one semiconductor chip facing away from the mounting surface are flush with a surface of the encapsulation material.

Example 18 is a semiconductor package according to one of Examples 12 to 17, wherein the electrically conductive chip carrier is structured at a surface of the electrically conductive chip carrier opposite to the mounting surface, thereby forming electric contact elements configured for a connection to a printed circuit board.

Example 19 is a semiconductor package according to Example 18, wherein: the encapsulation material is arranged between the carrier portion and the at least one semiconductor chip, the encapsulation material comprises fillers having a filler cut, and a distance between the carrier portion and the at least one semiconductor chip is at least two times the filler cut.

Example 20 is a semiconductor package according to one of Examples 12 to 19, wherein the chip carrier comprises a half etched leadframe.

As employed in this specification, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the word “over” used with regard to e.g. a material layer formed or located “over” a surface of an object may be used herein to mean that the material layer may be located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or multiple additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the term “exemplary” (or “for example”) is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

Although the disclosure has been shown and described with respect to one or multiple implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or multiple other features of the other implementations as may be desired and advantageous for any given or particular application.

1. A method for manufacturing a semiconductor package, the method comprising:
providing an electrically conductive chip carrier comprising a mounting surface and a protrusion extending out of the mounting surface;
arranging at least one semiconductor chip on the mounting surface;
encapsulating the protrusion and the at least one semiconductor chip in an encapsulation material, wherein surfaces of the protrusion and the at least one semiconductor chip facing away from the mounting surface remain uncovered by the encapsulation material; and
forming an electrical redistribution layer over the surfaces of the protrusion and the at least one semiconductor chip facing away from the mounting surface, wherein the electrical redistribution layer provides an electrical connection between the protrusion and the at least one semiconductor chip.

2. The method of claim 1, wherein forming the electrical redistribution layer is based on a thin film technology.

3. The method of claim 1, wherein encapsulating the protrusion and the at least one semiconductor chip comprises a molding act.

4. The method of claim 3, wherein during the molding act the surfaces of the protrusion and the at least one semiconductor chip facing away from the mounting surface are covered by a film.

5. The method of claim 4, wherein during the molding act the film is configured to compensate for height tolerances of at least one of the protrusion, the at least one semiconductor chip and a die attach material arranged between the at least one semiconductor chip and the mounting surface.

6. The method of claim 1, wherein providing the chip carrier comprises:
providing a metal sheet; and
removing material from a first surface of the metal sheet, thereby forming the protrusion.

7. The method of claim 6, wherein removing the material from the first surface comprises etching the first surface.

8. The method of claim 6, further comprising:
structuring a second surface of the metal sheet opposite to the first surface, thereby forming electric contact elements configured for a connection to a printed circuit board.

9. The method of claim 8, wherein at least one of the electric contact elements is electrically connected to the at least one semiconductor chip via the protrusion and the electrical redistribution layer.

10. The method of claim 8, further comprising:
arranging an electrically insulating material between the electrical contact elements.

11. The method of claim 1, further comprising:
forming a dielectric layer over the electrical redistribution layer; and
forming a further electrical redistribution layer over the dielectric layer, wherein the further electrical redistribution layer is electrically connected to the electrical redistribution layer.

12. A semiconductor package, comprising:
an electrically conductive chip carrier comprising a mounting surface and a carrier portion extending out of the mounting surface arranged laterally displaced to the mounting surface;
at least one semiconductor chip arranged on the mounting surface;
an encapsulation material encapsulating the carrier portion and the at least one semiconductor chip, wherein surfaces of the carrier portion and the at least one semiconductor chip facing away from the mounting surface are uncovered by the encapsulation material; and
an electrical redistribution layer formed over the surfaces of the carrier portion and the at least one semiconductor chip facing away from the mounting surface, wherein the electrical redistribution layer provides an electrical connection between the carrier portion and the at least one semiconductor chip.

13. The semiconductor package of claim 12, wherein the electrical redistribution layer comprises a thin film electrical redistribution layer.

14. The semiconductor package of claim 12, wherein the chip carrier comprises a leadframe.

15. The semiconductor package of claim 12, wherein the carrier portion forms an electrical through connection extending from a first surface of the encapsulation material to a second surface of the encapsulation material opposite to the first surface.

16. The semiconductor package of claim 12, wherein the surfaces of the carrier portion and the at least one semiconductor chip facing away from the mounting surface are arranged substantially on a same level.

17. The semiconductor package of claim 12, wherein the surfaces of the carrier portion and the at least one semiconductor chip facing away from the mounting surface are flush with a surface of the encapsulation material.

18. The semiconductor package of claim 12, wherein the electrically conductive chip carrier is structured at a surface of the electrically conductive chip carrier opposite to the mounting surface, thereby forming electric contact elements configured for a connection to a printed circuit board.

19. The semiconductor package of claim 18, wherein:
the encapsulation material is arranged between the carrier portion and the at least one semiconductor chip,
the encapsulation material comprises fillers having a filler cut, and
a distance between the carrier portion and the at least one semiconductor chip is at least two times the filler cut.

20. The semiconductor package of claim 12, wherein the chip carrier comprises a half etched leadframe.
